(19) United States
(12) Patent Application Publication
(10) Pub. No.: US 2026/0223421 A1
(43) Pub. Date: Jul. 30, 2026

(54) SEMICONDUCTOR DEVICE AND DISPLAY PANEL

(71) Applicant: Guangzhou China Star Optoelectronics Semiconductor Display Technology Co., Ltd., Guangzhou (CN)

(72) Inventors: Bin ZHAO, Guangzhou (CN); Juncheng XIAO, Guangzhou (CN); Xiaolin YAN, Guangzhou (CN); Shan LI, Guangzhou (CN); Jingdong LIU, Guangzhou (CN); Daobing HU, Guangzhou (CN)

(73) Assignee: Guangzhou China Star Optoelectronics Semiconductor Display Technology Co., Ltd., Guangzhou (CN)

(21) Appl. No.: 19/253,930

(22) Filed: Jun. 29, 2025

(30) Foreign Application Priority Data
Jan. 24, 2025 (CN) 202510121566.8

(51) Int. Cl. H10D 62/60; H10D 30/67; H10D 86/60

(52) U.S. Cl. CPC H10D 62/60; H10D 30/6731; H10D 30/6732; H10D 30/6755; H10D 86/60

(57) ABSTRACT

The application provides a semiconductor device and a display panel. The display panel includes a semiconductor device. The semiconductor device includes an active layer made of a semiconductor material. The semiconductor material is doped with tantalum, and at least one of terbium and praseodymium. The semiconductor material includes a metal oxide semiconductor material.

### CROSS-REFERENCE TO RELATED APPLICATION

This application claims priority to Chinese Patent Application No. 202510121566.8, filed on Jan. 24, 2025, the disclosure of which is incorporated herein by reference in its entirety.

### TECHNICAL FIELD

The present application relates to the technical field of display, and in particular to a semiconductor device and a display panel.

### BACKGROUND

In recent years, as a result of the development of liquid crystal technology, electroluminescence and related technologies, flat panel displays have been commercialized. They are driven by active matrix circuits including field effect thin film semiconductor devices that use amorphous silicon-based thin films as active layers formed on glass substrates. The performance of thin film semiconductor devices depends mainly on the properties of the active layer.

Amorphous silicon-based thin film semiconductor devices include thin film semiconductor devices including an active layer formed of amorphous silicon or thin film semiconductor devices including an active layer formed of polycrystalline silicon. The problem with amorphous silicon thin film semiconductor devices is that since the charge mobility is about 0.5 cm²/(V*s), it is difficult to increase the operating speed of the display device. The problem with polycrystalline silicon thin film semiconductor devices is that since crystallization, impurity doping and activation processes are required, the manufacturing process is more complicated and the manufacturing cost is higher than that of amorphous silicon thin film semiconductor devices. In addition, the problem with polycrystalline silicon thin film semiconductor devices is that since it is difficult to ensure the uniformity of the polycrystalline silicon layer, the image quality is reduced when the polycrystalline silicon layer is used as an active layer of a large-sized display device.

In order to realize the next generation of high-performance, high-resolution, large-size display devices, thin-film semiconductor devices with excellent performance are required. For this purpose, oxide semiconductor films, such as Indium Gallium Zinc Oxide (IGZO) films, have been developed and used as active layers of thin-film semiconductor devices. However, the mobility and light stability of traditional oxide thin-film semiconductor devices need to be improved.

### SUMMARY

The present application provides a semiconductor device and a display panel to improve the mobility and light stability of an oxide thin film semiconductor device.

To solve the above problems, the present application provides the following technical solutions.

An embodiment of the present application provides a semiconductor device, which includes an active layer made of a semiconductor material doped with tantalum, and at least one of terbium and praseodymium;
where, the semiconductor material includes a metal oxide semiconductor material.

In the semiconductor device provided in an embodiment of the present application, the atomic percentage of tantalum in the semiconductor material is greater than or equal to 10% and less than or equal to 40%, the atomic percentage of terbium is less than or equal to 10%, and/or the atomic percentage of praseodymium is less than or equal to 10%.

In the semiconductor device provided in an embodiment of the present application, the semiconductor material also includes indium, where the atomic percentage of the indium is greater than or equal to 60% and less than or equal to 90%.

In the semiconductor device provided in an embodiment of the present application, the tantalum doped in the semiconductor material has a valence of +5.

In the semiconductor device provided in an embodiment of the present application, the semiconductor device further includes a gate electrode, and a source electrode and a drain electrode connected to the active layer, and the semiconductor device is configured so that the current between the source electrode and the drain electrode is less than 10⁻⁵ A when no gate voltage is applied to the gate electrode.

In the semiconductor device provided in an embodiment of the present application, the metal oxide semiconductor material has a crystalline structure and/or an amorphous structure.

In the semiconductor device provided in an embodiment of the present application, the metal oxide semiconductor material includes indium oxide.

In the semiconductor device provided in an embodiment of the present application, the mobility of the active layer increases with the increase of the carrier concentration in the active layer.

In the semiconductor device provided in an embodiment of the present application, the carrier concentration of the active layer is greater than or equal to 10¹⁹ cm⁻³ and less than 10²⁰ cm⁻³.

In the semiconductor device provided in an embodiment of the present application, the band gap of the active layer is greater than or equal to 3.0 eV and less than or equal to 3.8 eV.

An embodiment of the present application further provides a display panel, which includes the semiconductor device described in any of the aforementioned embodiments.

In the semiconductor device and display panel provided in an embodiment of the present application, the semiconductor material of the active layer in the semiconductor device is doped with tantalum and at least one of terbium and praseodymium, and the semiconductor material includes a metal oxide semiconductor material. By doping the semiconductor material with a specific content of tantalum which is an n-type doping, the effective mass of electrons is small, and the 5s spherical electron orbit can increase the degree of electron cloud overlap, thereby increasing the mobility. By doping the semiconductor material with a specific content of at least one of terbium and praseodymium, the terbium and praseodymium will generate acceptor-type trap states at the bottom of the conduction band, thereby capturing photoelectrons, thereby effectively forming a photogenerated carrier recombination center and improving photostability. By doping the semiconductor material with a specific content of tantalum and terbium, the heterostructure in the semiconductor material can be increased, and the semiconductor material can be transformed from a polycrystalline state to an amorphous state to adapt to the preparation of large-generation line oxide semiconductor devices.

### BRIEF DESCRIPTION OF THE DRAWINGS

In order to more clearly illustrate the technical solutions in the embodiments or the prior art, the drawings required for use in the embodiments or the description of the prior art will be briefly introduced below. Obviously, the drawings described below are only some embodiments of the invention. For those skilled in this field, other drawings can be obtained based on these drawings without paying any creative work.

FIG. 1 is a schematic diagram showing a cross-sectional structure of a semiconductor device according to an embodiment of the present application.

FIG. 2 is a schematic showing a cross-sectional structure diagram of a semiconductor device according to another embodiment of the present application.

### DETAILED DESCRIPTION

The following descriptions of the embodiments are with reference to the attached diagrams to illustrate specific embodiments that the present application can be implemented in. The directional terms mentioned in the present application, such as “up”, “down”, “front”, “back”, “left”, “right”, “inside”, “outside”, “side”, etc., are only with reference to the directions of the attached drawings. Therefore, the directional terms used aim to illustrate and understand the present application, rather than to limit the present application. In the figures, units with similar structures are represented by the same reference numerals. In the accompanying drawings, the thickness of some layers and regions is exaggerated for clear understanding and ease of description. That is, the size and thickness of each component shown in the drawings are arbitrarily shown, but the present application is not limited to this.

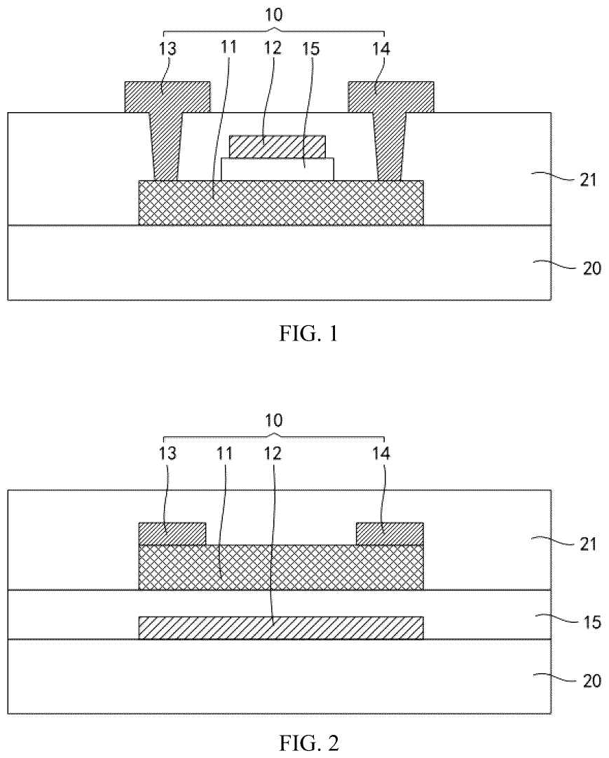

Please refer to FIGS. 1 and 2, FIG. 1 is a schematic diagram showing a cross-sectional structure of a semiconductor device according to an embodiment of the present application, and FIG. 2 is a schematic diagram showing a cross-sectional structure of a semiconductor device according to another embodiment of the present application. The semiconductor device 10 includes an active layer 11, a gate electrode 12, a source electrode 13, a drain electrode 14, and a gate insulating layer 15 located between the active layer 11 and the gate electrode 12. The difference between the semiconductor devices 10 in FIGS. 1 and 2 is that the semiconductor device 10 in FIG. 1 has a top gate structure, that is, the gate electrode 12 is located above the active layer 11, while the semiconductor device 10 in FIG. 2 has a bottom gate structure, that is, the gate electrode 12 is located below the active layer 11. However, the structure of the semiconductor device 10 of the present application is not limited thereto, and the structure of the semiconductor device 10 in FIGS. 1 and 2 is only for illustration.

An embodiment of the present application takes the structure of the semiconductor device 10 illustrated in FIG. 2 as an example. Referring to FIG. 2, the semiconductor device 10 is disposed on a substrate 20. The substrate 20 may be a glass substrate, or any of various substrates used in a general semiconductor device process, such as a plastic substrate or a silicon substrate. The substrate 20 may be an inorganic substrate or an organic substrate, and may be transparent, opaque, or translucent.

The gate electrode 12 of the semiconductor device 10 is disposed on the substrate 20. The gate electrode 12 may be formed of a general electrode material (e.g., a metal, an alloy, a conductive metal oxide, a conductive metal nitride, etc.). For example, the gate electrode 12 may be formed of a metal such as titanium (Ti), platinum (Pt), ruthenium (Ru), gold (Au), silver (Ag), molybdenum (Mo), aluminum (Al), tungsten (W), copper (Cu), neodymium (Nd), chromium (Cr), tantalum (Ta), or an alloy including the metal, or a conductive oxide such as indium zinc oxide (IZO), aluminum zinc oxide (AZO), indium tantalum oxide (ITO), gallium zinc oxide (GZO) or zinc tantalum oxide (ZTO) or a compound including a conductive oxide. The gate electrode 12 may have a single-layer structure or a multi-layer structure.

The gate insulating layer 15 covers the gate electrode 12 and the substrate 20. The gate insulating layer 15 may include a silicon oxide (SiOx) layer, a silicon oxynitride (SiOxNy) layer, or a silicon nitride (SiNx) layer, or may include another material layer such as a high-k material (e.g., HfO₂ or Al₂O₃) layer having a dielectric constant higher than that of a silicon nitride layer. The gate insulating layer 15 may have a structure in which at least two layers of a silicon oxide layer, a silicon oxynitride layer, a silicon nitride layer, and a high-k material layer are stacked. For example, the gate insulating layer 15 may have a structure in which a silicon nitride layer and a silicon oxide layer are stacked. In this case, the silicon nitride layer and the silicon oxide layer may be sequentially disposed on the gate electrode 12. Although not shown in FIG. 2, a predetermined lower layer may be disposed on the substrate 20, and the gate electrode 12 and the gate insulating layer 15 covering the gate electrode 12 may be disposed on the lower layer. The lower layer may be an insulating layer, such as an oxide layer. The oxide layer may be, for example, a silicon oxide layer. However, the material of the lower layer may be changed in various ways.

The active layer 11 is disposed on a side of the gate insulating layer 15 facing away from the gate electrode 12. The active layer 11 may be disposed above the gate electrode 12 to align with the gate electrode 12. The width of the active layer 11 may be greater than the width of the gate electrode 12. However, in some cases, the width of the active layer 11 may be similar to or less than the width of the gate electrode 12.

The source electrode 13 and the drain electrode 14 are located on a side of the active layer 11 facing away from the gate electrode 12. Optionally, the source electrode 13 and the drain electrode 14 are located on the active layer 11 and directly contact the active layer 11. The active layer 11 includes a channel portion and a source contact portion and a drain contact portion located on both sides of the channel portion, and the channel portion connects the source contact portion and the drain contact portion. The source electrode 13 is connected to the source contact portion, and the drain electrode 14 is connected to the drain contact portion. The gate electrode 12 is at least arranged corresponding to the channel portion.

The source electrode 13 and the drain electrode 14 may each have a single-layer structure or a multi-layer structure. The materials of the source electrode 13 and the drain electrode 14 may be the same as or similar to the material of the gate electrode 12. The source electrode 13 and the drain electrode 14 may each be formed of the same material as the gate electrode 12, or may be formed of a material different from the gate electrode 12. For example, each of the source electrode 13 and/or the drain electrode 14 may be formed of a metal such as Ti, Pt, Ru, Au, Ag, Mo, Al, W, Cu, Nd, Cr, Ta, or an alloy including the metal, or a conductive oxide such as IZO, AZO, ITO, GZO or ZTO, or a compound including a conductive oxide.

A passivation layer 21 is provided at a side of the source electrode 13 and the drain electrode 14 that faces away from the active layer 11. The passivation layer 21 may be a silicon oxide layer, a silicon oxynitride layer, a silicon nitride layer or an organic layer, or may have a structure in which at least two of a silicon oxide layer, a silicon oxynitride layer, a silicon nitride layer and an organic layer are stacked. For example, the passivation layer 21 may have a single-layer structure formed of silicon oxide or silicon nitride, or a multilayer structure including a silicon oxide layer and a silicon nitride layer disposed on the silicon oxide layer. In addition, the passivation layer 21 may have a multilayer structure including two or more layers. In this case, the passivation layer 21 may include a silicon oxide layer, a silicon oxynitride layer and a silicon nitride layer stacked in sequence.

The material of the active layer 11 includes a semiconductor material, which includes, for example, a metal oxide semiconductor material such as indium oxide, and the metal oxide semiconductor material may have a crystalline structure and/or an amorphous structure. The active layer 11 may be formed of a semiconductor material by using, for example, physical vapor deposition (PVD) such as sputtering. The sputtering may be reactive sputtering. In addition, the sputtering may be co-sputtering using multiple targets. When forming a semiconductor material by using co-sputtering, nitrogen (N₂) or oxygen (O₂) can be used as a reaction gas, and argon (Ar) may also be used. Nitrogen can be a source of nitrogen, and oxygen can be a source of oxygen. Argon can serve as a carrier gas. In addition, argon can improve deposition efficiency by generating plasma. The flow rate of nitrogen may be in a range from about 20 sccm to about 200 sccm, and the flow rate of oxygen can range from about 1 sccm to about 15 sccm. The flow rate of argon may be in a range from about 1 sccm to about 100 sccm. The supply amount of nitrogen can be greater than the supply amount of oxygen. For example, the supply amount of nitrogen may be 10 times or more, or 50 times or more, that of oxygen.

In some embodiments, the semiconductor material of the active layer 11 is doped with tantalum (Ta), and at least one of terbium (Tb) and praseodymium (Pr). That is, in some embodiments, the semiconductor material of the active layer 11 is doped with tantalum and terbium; in other embodiments, the semiconductor material of the active layer 11 is doped with tantalum and praseodymium; in other embodiments, the semiconductor material of the active layer 11 is doped with tantalum, terbium and praseodymium.

The atomic percentage of tantalum in the semiconductor material is greater than or equal to 10% and less than or equal to 40%, that is, the content of tantalum in the semiconductor material of the active layer 11 is 10 at %≤Ta at %≤40 at %, for example, the content of tantalum is 10 at %, 12 at %, 15 at %, 17 at %, 19 at %, 20 at %, 22 at %, 23 at %, 26 at %, 28 at %, 30 at %, 33 at %, 36 at %, 38 at %, 40 at %, etc.

It should be noted that “at %” means atomic percentage.

The atomic percentage of terbium in the semiconductor material is less than or equal to 10%, and/or the atomic percentage of praseodymium is less than or equal to 10%. In an embodiment of the present application, the semiconductor material includes terbium as an example. The atomic percentage of terbium in the semiconductor material is less than or equal to 10%, that is, the content of terbium in the semiconductor material of the active layer 11 is 0 at %<Tb at %≤10 at %, for example, the content of terbium is 0.1 at %, 0.5 at %, 1 at %, 1.5 at %, 1.8 at %, 2 at %, 2.6 at %, 2.9 at %, 3 at %, 3.3 at %, 3.6 at %, 4 at %, 4.3 at %, 4.6 at %, 5 at %, 5.5 at %, 6 at %, 6.5 at %, 7 at %, 7.5 at %, 8 at %, 8.5 at %, 9 at %, 9.5 at %, 10 at %, etc.

In this way, by doping the semiconductor material of the active layer 11 with a specific content of tantalum, which is an n-type doping, the electron effective mass is small, and the 5s spherical electron orbit can increase the degree of electron cloud overlap, thereby increasing the mobility. By doping the semiconductor material with a specific content of at least one of terbium and praseodymium, terbium and praseodymium will generate acceptor-type trap states at the bottom of the conduction band, thereby capturing photoelectrons, thereby effectively forming a photogenerated carrier recombination center and improving photostability. By doping the semiconductor material with a specific content of tantalum and terbium, the heterostructure in the semiconductor material can be increased, and the semiconductor material can be transformed from a polycrystalline state to an amorphous state to adapt to the preparation of large-generation line oxide semiconductor devices. In addition, by doping the semiconductor material with a specific content of tantalum and at least one of terbium and praseodymium, the tantalum, terbium, and praseodymium elements will combine with oxygen to form compounds to reduce oxygen vacancies in the semiconductor material, thereby reducing the oxygen defect density.

In some embodiments, the semiconductor material further includes indium, the atomic percentage of indium (In) is greater than or equal to 60% and less than or equal to 90%. That is, the content of indium in the semiconductor material of the active layer 11 is 60 at %≤Tb at %≤90 at %, for example, the content of indium is 60 at %, 63 at %, 65 at %, 67 at %, 70%, 72 at %, 75 at %, 78 at %, 80 at %, 83 at %, 87 at %, 89 at %, 90 at %, etc.

In some embodiments, the tantalum doped in the semiconductor material has the valence of +5. Compared with In capturing 3 electrons, Ta having the valence of +5 can passivate and attract negative electric centers, such as O²⁻, OH⁻, etc., thereby reducing the oxygen-related defect density. Moreover, the tantalum has the valence of +5 and can form n-type doping. Ta replaces In, and two extra free electrons become n-type carriers, such as Ta+In³⁺→Ta⁵⁺+2e⁻+In. Ta is an n-type doping, the effective mass of the electron is small, and the 5s spherical electron orbit can increase the degree of electron cloud overlap and increase the mobility.

In some embodiments, the mobility of the active layer 11 increases with the increase of the carrier concentration in the active layer 11. For example, in the present application, the carrier concentration of the active layer 11 is greater than or equal to 10¹⁹ cm⁻³ and less than 10²⁰ cm⁻³. The bandgap width of the active layer 11 is greater than or equal to 3.0 eV and less than or equal to 3.8 eV.

In some embodiments, the present application dopes tantalum, terbium and praseodymium into the semiconductor material of the active layer 11, thereby improving the mobility and photostability while reducing the off-state circuit of the semiconductor device 10. For example, the semiconductor device is configured such that the current between the source electrode 13 and the drain electrode 14 is less than 10⁻⁵ A when no gate voltage is applied to the gate electrode 12.

Based on the same inventive concept, an embodiment of the present application further provides a display panel including the semiconductor device 10 described in one of the aforementioned embodiments. The display panel comprises any of a liquid crystal display panel, a light-emitting diode (LED) display panel, a micro light-emitting diode (Micro-LED) display panel or a sub-millimeter light-emitting diode (Mini-LED) display panel.

In a semiconductor device and a display panel according to embodiment of the present application, the semiconductor material of the active layer in the semiconductor device is doped with tantalum and at least one of terbium and praseodymium. The atomic percentage of tin is greater than or equal to 10% and less than or equal to 40%, the atomic percentage of terbium is less than or equal to 10%, and/or the atomic percentage of praseodymium is less than or equal to 10%. By doping the semiconductor material with a specific content of tantalum, which is n-type doping, the electron effective mass is small, and the 5s spherical electron orbit can increase the degree of electron cloud overlap, thereby increasing the mobility. By doping a semiconductor material with a specific content of at least one of terbium and praseodymium. the terbium and praseodymium will generate acceptor-type trap states at the bottom of the conduction band, thereby capturing photoelectrons, thereby effectively forming photogenerated carrier recombination centers and improving photostability. By doping the semiconductor material with tantalum and terbium, the heterostructure in the semiconductor material can be increased, and the semiconductor material can be transformed from a polycrystalline state to an amorphous state to adapt to the preparation of large-generation line oxide semiconductor devices.

In the above embodiments, the description of each embodiment has its own emphasis. For parts that are not described in detail in a certain embodiment, reference can be made to the relevant descriptions of other embodiments.

The embodiments of the present application are introduced in detail above. Specific examples are used in this article to illustrate the principles and implementation methods of the present application. The description of the above embodiments is only used to help understand the technical solution and core idea of the present application. Those skilled in this field should understand that they can still modify the technical solutions recorded in the aforementioned embodiments, or replace some of the technical features therein with equivalents; and these modifications or replacements do not make the essence of the corresponding technical solutions deviate from the scope of the technical solutions of the embodiments of the present application.

What is claimed is:

1. A semiconductor device, comprising an active layer made of a semiconductor material, wherein the semiconductor material is doped with tantalum, and at least one of terbium and praseodymium; and
wherein, the semiconductor material comprises a metal oxide semiconductor material.

2. The semiconductor device according to claim 1, wherein in the semiconductor material, an atomic percentage of the tantalum is greater than 10% and less than 40%, or is equal to 10% or 40%; and
an atomic percentage of the terbium is less than or equal to 10%, and/or an atomic percentage of the praseodymium is less than or equal to 10%.

3. The semiconductor device according to claim 2, wherein the semiconductor material comprises indium, wherein an atomic percentage of the indium is greater than 60% and less than 90%, or is equal to 60% or 90%.

4. The semiconductor device according to claim 1, wherein the tantalum doped in the semiconductor material has a valence of +5.

5. The semiconductor device according to claim 1, further comprising a gate electrode, a source electrode and a drain electrode, wherein the source electrode and the drain electrode are connected to the active layer, wherein the semiconductor device is configured such that a current between the source electrode and the drain electrode is less than 10⁻⁵ A when no gate voltage is applied to the gate electrode.

6. The semiconductor device according to claim 1, wherein the metal oxide semiconductor material comprises a crystalline structure and/or an amorphous structure.

7. The semiconductor device according to claim 6, wherein the metal oxide semiconductor material comprises indium oxide.

8. The semiconductor device according to claim 1, wherein a mobility of the active layer increases with an increase of a carrier concentration of the active layer.

9. The semiconductor device according to claim 8, wherein the carrier concentration of the active layer is greater than 10¹⁹ cm⁻³ and less than 10²⁰ cm⁻³, or is equal to 10¹⁹ cm⁻³.

10. The semiconductor device according to claim 8, wherein a band gap of the active layer is greater than 3.0 eV and less than 3.8 eV, or is equal to 3.0 eV or 3.8 eV.

11. A display panel, comprising a semiconductor device, wherein the semiconductor device comprises an active layer made of a semiconductor material, wherein the semiconductor material is doped with tantalum, and at least one of terbium and praseodymium; and
wherein, the semiconductor material comprises a metal oxide semiconductor material.

12. The display panel according to claim 11, wherein in the semiconductor material, an atomic percentage of the tantalum is greater than 10% and less than 40%, or is equal to 10% or 40%, an atomic percentage of the terbium is less than or equal to 10%, and/or an atomic percentage of the praseodymium is less than or equal to 10%.

13. The display panel according to claim 12, wherein the semiconductor material comprises indium, wherein an atomic percentage of the indium is greater than 60% and less than 90%, or is equal to 60% or 90%.

14. The display panel according to claim 11, wherein the tantalum doped in the semiconductor material has a valence of +5.

15. The display panel according to claim 11, further comprising a gate electrode, a source electrode and a drain electrode, wherein the source electrode and the drain electrode are connected to the active layer, wherein the semiconductor device is configured such that a current between the source electrode and the drain electrode is less than 10⁻⁵ A when no gate voltage is applied to the gate electrode.

16. The display panel according to claim 11, wherein the metal oxide semiconductor material comprises a crystalline structure and/or an amorphous structure.

17. The display panel according to claim 16, wherein the metal oxide semiconductor material comprises indium oxide.

18. The display panel according to claim 11, wherein a mobility of the active layer increases with an increase of a carrier concentration of the active layer.

19. The display panel according to claim 18, wherein the carrier concentration of the active layer is greater than 10¹⁹ cm⁻³ and less than 10²⁰ cm⁻³, or is equal to 10¹⁹ cm⁻³.

20. The display panel according to claim 18, wherein a band gap of the active layer is greater than 3.0 eV and less than 3.8 eV, or is equal to 3.0 eV or 3.8 eV.
